(19) United States
(12) Patent Application Publication
(10) Pub. No.: US 2024/0395654 A1
(43) Pub. Date: Nov. 28, 2024

(54) STACKED SEMICONDUCTOR DEVICE HAVING A HEAT DISSIPATION STRUCTURE

(71) Applicant: TAIWAN SEMICONDUCTOR MANUFACTURING COMPANY, LTD., Hsincu (TW)

(72) Inventor: Jen-Yuan Chang, Hsinchu (TW)

(73) Assignee: TAIWAN SEMICONDUCTOR MANUFACTURING COMPANY, LTD., Hsinchu (TW)

(21) Appl. No.: 18/323,732

(22) Filed: May 25, 2023

(51) Int. Cl. H01L 23/367; H01L 23/00; H01L 25/00; H01L 25/065

(52) U.S. Cl. CPC H01L 23/3675; H01L 24/29; H01L 24/32; H01L 24/83; H01L 25/0652; H01L 25/50; H01L 24/11; H01L 2224/11002; H01L 2224/2919; H01L 2224/29193; H01L 2224/32237; H01L 2224/32257; H01L 2224/83005; H01L 2224/83104; H01L 2224/83385; H01L 2224/83417; H01L 2224/83438; H01L 2224/83486; H01L 2224/83908; H01L 2924/01014; H01L 2924/01031; H01L 2924/01033; H01L 2924/0132; H01L 2924/04642; H01L 2924/0523; H01L 2924/0665

(57) ABSTRACT

A stacked semiconductor device includes a first die, and a second die, a third die and a heat dissipation component that are bonded to the first die. The heat dissipation component is formed in one piece, and is adjacent to at least two edges of each of the second die and the third die.

### BACKGROUND

A semiconductor chip may be composed of multiple dies. In order to reduce area occupied by the multiple dies and to increase performance of the chip, techniques to stack and integrate the dies together are developed. Various bonding techniques may be used to form the stack structure, such as wafer-to-wafer bonding, die-to-wafer bonding, die-to-die bonding, fusion bonding, hybrid bonding (e.g., including metal-to-metal bonding and dielectric-to-dielectric bonding at the same time), etc.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic diagram that illustrates a top view of a stacked semiconductor device in accordance with some embodiments.

FIG. 2 is a sectional view that illustrates the stacked semiconductor device taken along line A-A in FIG. 1 in accordance with some embodiments.

FIG. 3 is a sectional view that illustrates a first die of the stacked semiconductor device in accordance with some embodiments.

FIG. 4 is a flow chart that illustrates steps of a method for fabricating the stacked semiconductor device in accordance with some embodiments.

FIGS. 5 to 12 are sectional views showing structures in intermediate stages of the method for fabricating the stacked semiconductor device in accordance with some embodiments.

FIG. 13 is a schematic diagram that illustrates a top view of a stacked semiconductor device in accordance with some embodiments.

FIG. 14 is a sectional view that illustrates the stacked semiconductor device taken along line C-C in FIG. 13 in accordance with some embodiments.

FIG. 15 is a sectional view that illustrates the stacked semiconductor device taken along line D-D in FIG. 13 in accordance with some embodiments.

FIG. 16 is a sectional view that illustrates a heat dissipation component of the stacked semiconductor device taken along line E1-E1 in FIG. 13 in accordance with some embodiments.

FIG. 17 is a flow chart that illustrates steps of a method for fabricating the stacked semiconductor device in accordance with some embodiments.

FIGS. 18 to 27 are sectional views showing structures in intermediate stages of the method for fabricating the stacked semiconductor device in accordance with some embodiments.

FIGS. 28 to 35 are top views and sectional views of different variations of the heat dissipation component of the stacked semiconductor device in accordance with some embodiments.

FIG. 36 is a top view that illustrates a variation of the stacked semiconductor device in accordance with some embodiments.

FIG. 37 is a sectional view that illustrates the variation of the stacked semiconductor device taken along line F-F in FIG. 36 in accordance with some embodiments.

FIGS. 38 and 39 are sectional view that illustrate various examples of final products that include the stacked semiconductor device in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “on,” “above,” “over,” “downwardly.” “upwardly,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

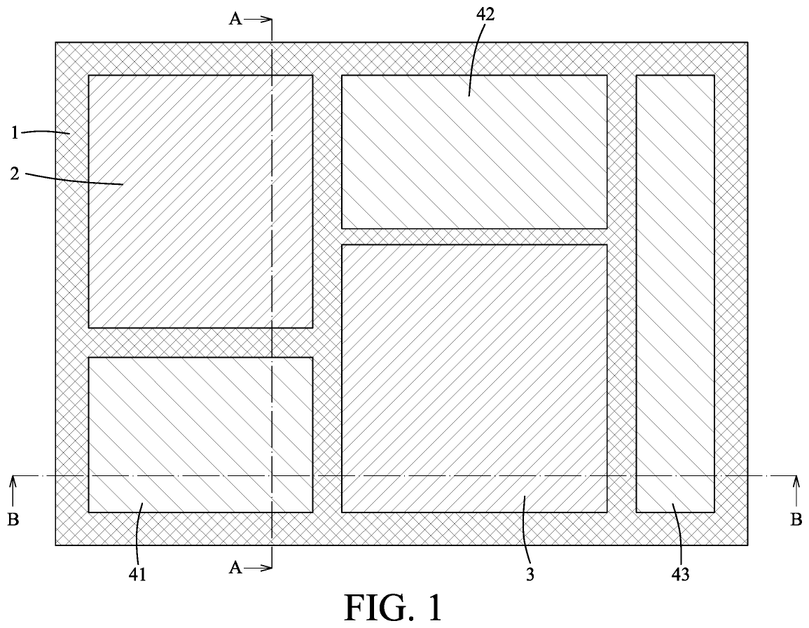

FIG. 1 illustrates a top view of a stacked semiconductor device in accordance with some embodiments. The stacked semiconductor device includes a first die 1, a second die 2, a third die 3, and a heat dissipation structure that includes a first dummy die 41, a second dummy die 42 and a third dummy die 43. The first die 1 is a bottom die of the stacked semiconductor device (the die in a first layer), and the second die 2 and the third die 3 are in a second layer that is over the first layer. It is noted that the illustrative embodiment is provided only for ease of explanation, and this disclosure is not limited to specific quantities and arrangements of dies and dummy dies. In the illustrative embodiment, the first die 1 is greater than the second die 2 and the third die 3 in length and width, and the second die and the third die are bonded to the first die 1. In order to enhance the uniformity and efficiency in heat dissipation, the first dummy die 41, the second dummy die 42 and the third dummy die 43 are bonded to the first die 1 at regions that are not occupied by the second die 2 or the third die 3. In accordance with some embodiments, the dummy dies 41, 42, 43 may be fabricated using a silicon wafer under a general photolithography process (e.g., a process to form shallow trench isolation (STI) structures), and thus each of the dummy dies 2, 3 may be a bulk of single-crystal silicon whose thermal conductivity is about 149 W/(m·K), which is much greater than that of SiO₂ (about 1.1 W/(m·K)). Depending on the type of the silicon wafer used to fabricate the dummy dies 41, 42, 43, the dummy dies 41, 42, 43 may have some n-type dopants (e.g., phosphorus, antimony, arsenic, etc.) or p-type dopants (e.g., boron, indium, etc.) in accordance with some embodiments. In other embodiments, the dummy dies 41, 42, 43 may be fabricated using other suitable materials, such as other types of semiconductor wafers (e.g., GaAs wafers, InP wafers, SiC wafers, etc.), and this disclosure is not limited in this respect.

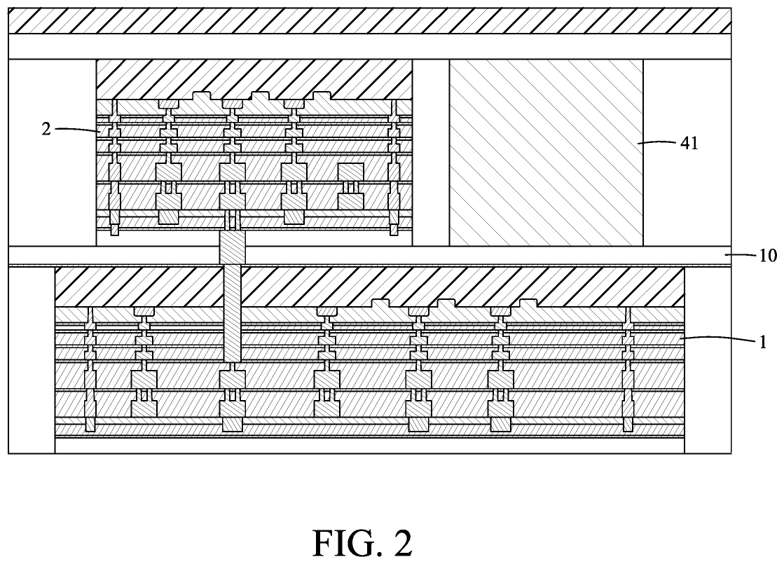

FIG. 2 illustrates an example of a sectional view taken along line A-A in FIG. 1. The first die 1 is formed with a dielectric layer 10 (e.g., a SiO₂ layer, a layer of other suitable materials, or any combination thereof) on top, where the dielectric layer 10 is embedded with at least one metal pad (e.g., made of copper, gold, other suitable metals, or any combination thereof). The second die 2 is bonded to the first die 1 using, for example, hybrid bonding (e.g., including metal-to-metal bonding and dielectric-to-dielectric bonding at the same time), so the first die 1 and the second die 2 are physically and electrically connected to each other. The third die 3 may be bonded to the first die 1 in a similar manner, so details thereof are omitted herein for the sake of brevity.

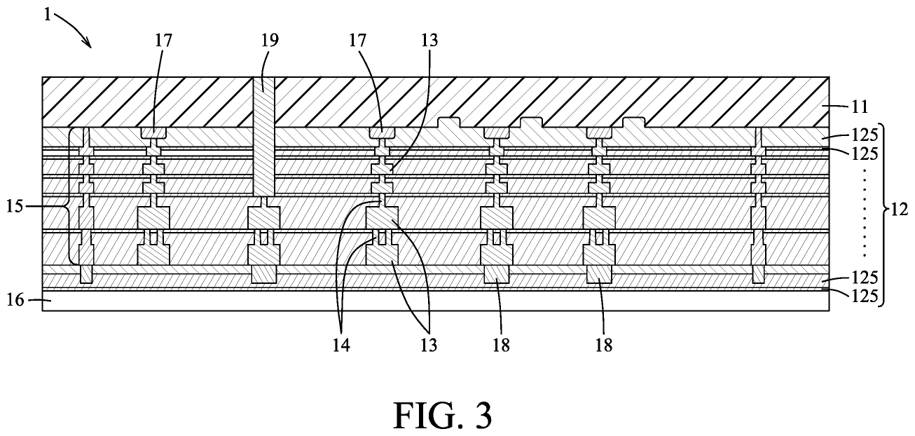

Referring to FIG. 3, the first die 1 includes a substrate 11, a dielectric structure 12, one or more wiring layers 13, a plurality of inner vias 14, a sealing structure 15, a dielectric film 16, a plurality of devices 17, one or more conductive pads 18, and at least one interconnection feature 19. The substrate 11 can be, for example, a silicon substrate.

The dielectric structure 12 is formed on the substrate 11. In the illustrative embodiment, the dielectric structure 12 includes a plurality of dielectric layers 125 that are stacked on one another. The dielectric layers 125 may include, for example, silicon oxide, silicon nitride, silicon carbide, phosphosilicate glass (PSG), undoped silicate glass (USG), tetraethoxysilane (TEOS) oxide, low-k materials, extreme low-k materials, other suitable materials, or any combination thereof.

The one or more wiring layers 13 are formed in the dielectric structure 12. Different wiring layers 13 may have electrical connections therebetween through the inner vias 14 that are embedded in the dielectric structure 12 between the wiring layers 13.

The sealing structure 15 is embedded in the dielectric structure 12, and is disposed around the wiring layer(s) 13 and the inner vias 14 to prevent the wiring layer(s) 13 and the inner vias 14 from corrosion by moisture.

The dielectric film 16 may include, for example, silicon oxide, other suitable materials, or any combination thereof.

The devices 17 may include, for example, metal-oxide-semiconductor field-effect transistors (MOSFETs), diodes, other types of circuit elements, or any combination thereof, and have electric connections with the wiring layers 13 through the inner vias 14.

The interconnection feature(s) 19 may include, for example, a through-silicon via (TSV), a through-oxide via (TOV), other suitable structures, or any combination thereof, configured for inter-die connections.

In accordance with some embodiments, the basic structures of the second die 2 and the third die 3 may be similar to that of the first die 1, so details thereof are omitted herein for the sake of brevity.

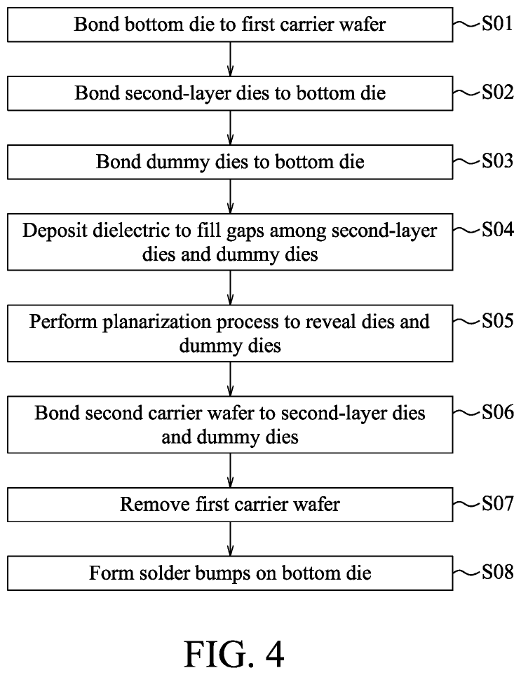

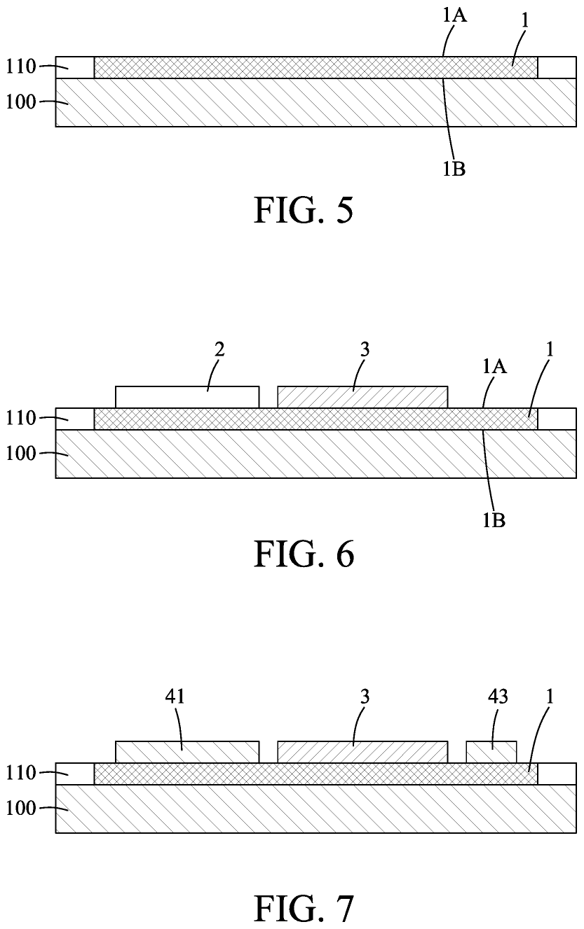

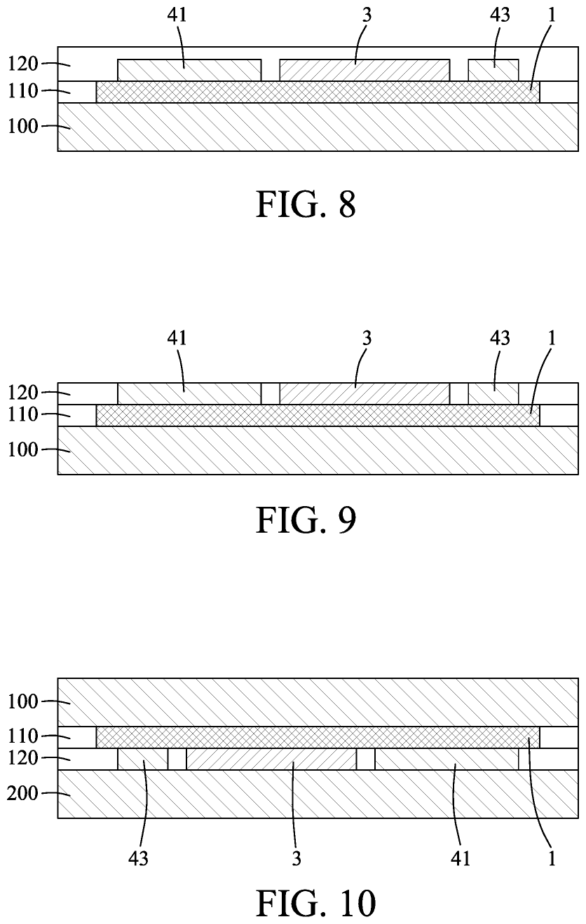

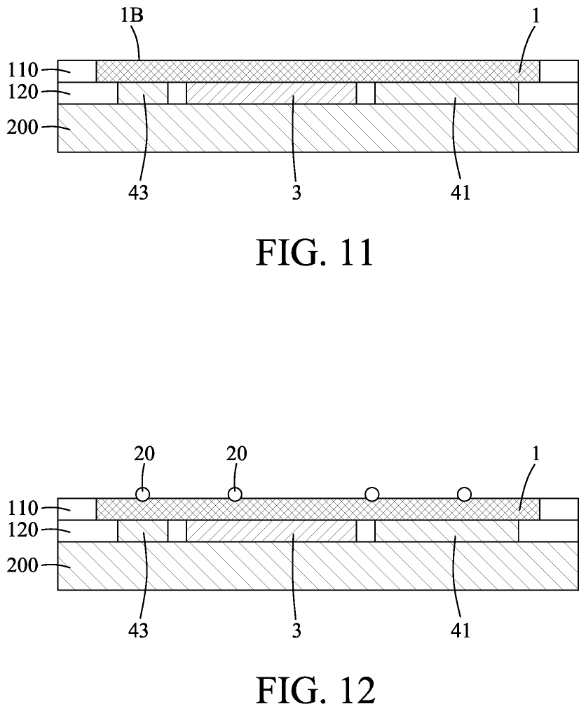

FIG. 4 illustrates a flow chart that cooperates with FIGS. 5 to 12 to illustrate a process for fabricating the stacked semiconductor device as shown in FIG. 1 in accordance with some embodiments, where FIGS. 5 to 12 are sectional views showing structures in intermediate stages of the process, as if taken along line B-B in FIG. 1.

Referring to FIGS. 1, 4 and 5, the first die 1 is bonded to a first carrier wafer 100 (step S01) using, for example, fusion bonding, other suitable techniques, or any combination thereof. The first die 1 has a first surface 1A, and a second surface 1B opposite to the first surface 1A, where the second surface 1B is connected to the first carrier wafer 100. Since the exemplary process is a wafer level process, there may be a plurality of dies bonded to the first carrier wafer 100, so a dielectric layer 110 may be formed to fill the gaps among the multiple dies. The dielectric layer 110 may include, for example, silicon oxide, silicon nitride, TEOS oxide, other suitable materials, or any combination thereof. The first carrier wafer 100 is used for enhancing the overall mechanical strength of the structure, so as to prevent mechanical damage from subsequent process steps.

Referring to FIGS. 1, 4 and 6, the second die 2 and the third die 3 are bonded to the first die 1 (step S02) using, for example, hybrid bonding, other suitable techniques, or any combination thereof. In accordance with some embodiments, a suction machine (not shown) may be used to pick and place the second die 2 and the third die 3 onto the first surface 1A of the first die 1 at respective predetermined regions, and then an annealing process may be used to bond the second die 2 and the third die 3 to the first die 1.

Referring to FIGS. 1, 4 and 7, the dummy dies 41, 42, 43 are bonded to the first die 1 (step S03) using, for example, fusion bonding, other suitable techniques, or any combination thereof. In accordance with some embodiments, the suction machine may be used to pick and place the dummy dies 41, 42, 43 onto the first surface 1A of the first die 1 at respective predetermined regions that are adjacent to the second die 2 and/or the third die 3, and then an annealing process is used to bond the dummy dies 41, 42, 43 to the first die 1.

In accordance with some embodiments, bonding of the dummy dies 41, 42, 43 (step S03) may be performed prior to bonding of the second and third dies 2, 3 (step S02). In accordance with some embodiments, the second and third dies 2, 3 and the dummy dies 41, 42, 43 may all be placed onto the first surface 1A of the first die 1 first, followed by an annealing process to bond all of these dies 2, 3, 41, 42, 43 to the first die 1, so as to reduce the overall processing time. However, bonding the second and third dies 2, 3 prior to bonding the dummy dies 41, 42, 43 may prevent particle pollutions during the bonding of the second and third dies 2, 3 that might otherwise arise from the picking and placing of the dummy dies 41, 42, 43.

Referring to FIGS. 1, 4 and 8, a dielectric layer 120 is deposited (step S04) to fill gaps among the second and third dies 2, 3 and the dummy dies 41, 42, 43. The dielectric layer 120 may include, for example, silicon oxide, silicon nitride, TEOS oxide, other suitable materials, or any combination thereof.

Referring to FIGS. 1, 4 and 9, a planarization process is performed on the dielectric layer 120 (step S05) to reveal top surfaces of the second and third dies 2, 3 and the dummy dies 41, 42, 43. As a result, the second and third dies 2, 3 and the dummy dies 41, 42, 43 may have the same thickness. In accordance with some embodiments, the planarization process may be, for example, a chemical-mechanical planarization (CMP) process, other suitable processes, or any combination thereof. Because the top surfaces of the second and third dies 2, 3 and the dummy dies 41, 42, 43 are usually made of silicon whose thermal conductivity is greater than that of the dielectric layer 120, revealing the top surfaces of the second and third dies 2, 3 and the dummy dies 41, 42, 43 may favor heat dissipation.

Referring to FIGS. 1, 4 and 10, a second carrier wafer 200 is bonded to the dielectric layer 120, the second and third dies 2, 3 and the dummy dies 41, 42, 43, and then the combined wafers and dies are flipped over for the following processes (step S06). In some embodiments, a bonding dielectric film (not shown) may be formed over the dielectric layer 120, the second and third dies 2, 3 and the dummy dies 41, 42, 43, and then the second carrier wafer 200 is bonded to the bonding dielectric film using, for example, fusion bonding, other suitable techniques, or any combination thereof. The second carrier wafer 200 is used for enhancing overall mechanical strength of the structure, so as to prevent mechanical damage from subsequent process steps.

Referring to FIGS. 1, 4 and 11, the first carrier wafer 100 (see FIG. 10) is removed (step S07) using, for example, a CMP process, a grinding process, other suitable thinning techniques, or any combination thereof, so as to reveal the second surface 1B of the first die 1. The second surface 1B of the first die 1 may be a surface of the dielectric film 16 (see FIG. 3).

Referring to FIGS. 1, 2, 4 and 12, a plurality of solder bumps 20 are formed onto the first die 1 (step S08) to connect with the conductive pads 18 of the first die 1 (see FIG. 3). In some embodiments, the dielectric film 16 and the dielectric structure 12 are etched to reveal the conductive pads 18, and then the solder bumps 20 are formed on the conductive pads 18.

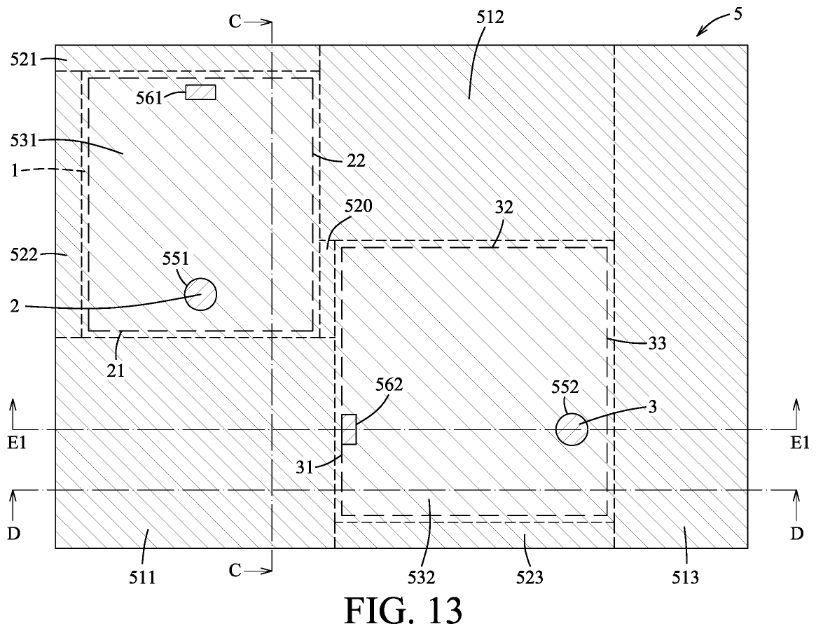

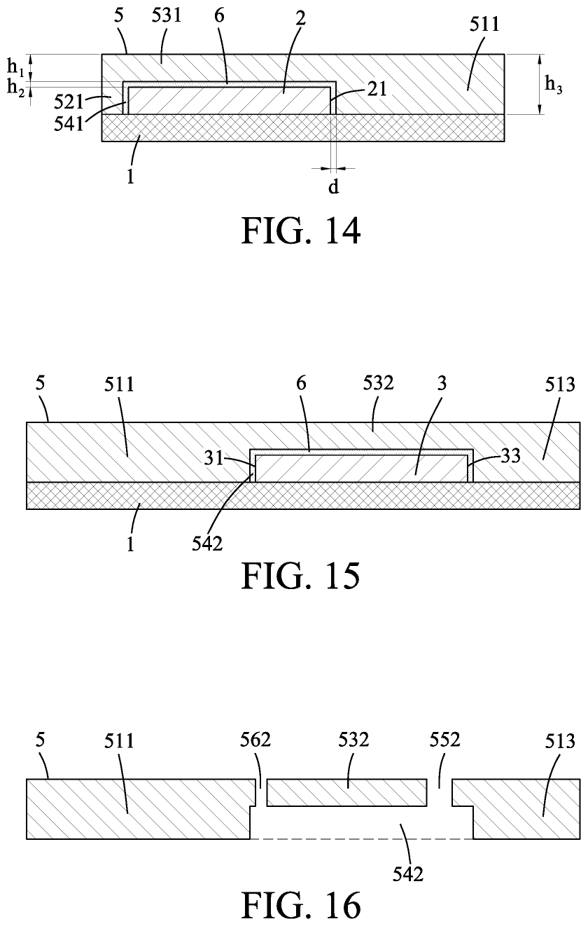

FIG. 13 illustrates a top view of a stacked semiconductor device in accordance with some embodiments, which differs from FIG. 1 in that the dummy dies 41, 42, 43 in FIG. 1 are replaced by a heat dissipation component 5 that is made as a cap to cover the second die 2 and the third die 3. The heat dissipation component 5 is made in one piece, and has a thermal conductivity greater than that of SiO₂ in order to achieve better heat dissipation capability. Similar to the dummy dies 41, 42, 43 in FIG. 1, the heat dissipation component 5 may be fabricated using a silicon wafer through a general photolithography process (e.g., a process to form STI structures), and thus may be a bulk of single-crystal silicon, but this disclosure is not limited in this respect. In other embodiments, the heat dissipation component 5 may be fabricated using other suitable materials, such as other types of semiconductor wafers (e.g., GaAs wafers, InP wafers, SiC wafers, etc.). FIGS. 14 and 15 are sectional views of the stacked semiconductor device taken along line C-C and line D-D in FIG. 13. The heat dissipation component 5 laterally surrounds and covers each of the second die 2 and the third die 3, and is formed with a first space 541 that corresponds in position to and accommodates the second die 2, and a second space 542 that corresponds in position to and accommodates the third die 3. In FIG. 13, the top view of the heat dissipation component 5 is virtually divided into multiple rectangular portions, which are respectively referred to as a first dummy die portion 511, a second dummy die portion 512, a third dummy die portion 513, an interconnection portion 520, a first framing portion 521, a second framing portion 522, a third framing portion 523, a first covering portion 531, and a second covering portion 532. In the illustrative embodiment, the heat dissipation component 5 has a flat top surface, namely, the top surfaces of the dummy die portions 511, 512, 513, the interconnection portion 520, the framing portions 521, 522, 523, and the covering portions 531, 532 are coplanar.

Each of the dummy die portions 511, 512, 513, the interconnection portion 520 and the framing portions 521, 522, 523 has a bottom surface attached to the first die 1 using, for example, fusion bonding. The first dummy die portion 511 has a first edge (or side surface) that extends in parallel with and is adjacent to an edge 21 of the second die 2, and a second edge that extends in parallel with and is adjacent to an edge 31 of the third die 3. The second dummy die portion 512 has a first edge that extends in parallel with and is adjacent to an edge 22 of the second die 2, and a second edge that extends in parallel with and is adjacent to an edge 32 of the third die 3. The third dummy die portion 513 has an edge that extends in parallel with and is adjacent to an edge 33 of the third die 3. An edge-to-edge distance “d” between the heat dissipation component 5 and the dies 2, 3 in a lateral direction may be determined based on precision of the suction machine in placing the dies and the heat dissipation component 5. For example, when the precision of the suction machine is ±1 μm, the edge-to-edge distance “d” may be designed to be greater than but close to about 2 μm, while in some embodiments, the edge-to-edge distance “d” may be designed down to about 0.01 μm. The interconnection portion 520 is disposed between the second die 2 and the third die 3, and interconnects the first dummy die portion 511 and the second dummy die portion 512. The dummy die portions 511. 512, the interconnection portion 520 and the framing portions 521, 522 cooperatively surround or enclose the second die 2. The dummy die portions 511, 512, 513, the interconnection portion 520 and the framing portion 523 cooperatively surround or enclose the third die 3.

The first covering portion 531 is connected to and cooperates with the dummy die portions 511, 512, the interconnection portion 520 and the framing portions 521, 522 to form the first space 541 that accommodates the second die 2, and is disposed over and covers the second die 2. The second covering portion 532 is connected to and cooperates with the dummy die portions 511, 512, 513, the interconnection portion 520 and the framing portion 523 to form the second space 542 that accommodates the third die 3, and is disposed over and covers the third die 3. In the illustrative embodiment, the covering portions 531, 532 are hanging portions that are not bonded to the first die 1, and are thinner than the dummy die portions 511, 512, 513, the interconnection portion 520, and the framing portions 521, 522, 523. In accordance with some embodiments, a thickness “h₁” of each of the covering portions 531, 532 is greater than about 100 μm in order to have sufficient mechanical strength to prevent damage that may be caused by a process of picking and placing the heat dissipation component 5 onto the first die 1. In some embodiments, the thickness “h₁” may be down to about 0.01 μm. A distance “h₂” between a die (e.g., the second die 2 or the third die 3) and the corresponding covering portion (e.g., the first covering portion 531 or the second covering portion 532), which is a dimension of a spacing between a top surface of the die and a bottom surface of the corresponding covering portion, may be determined based on manufacturing precision with respect to a thickness of the die. In accordance with some embodiments, the distance “h₂” may be designed to be greater than about 2 μm to accommodate for a tolerance for the variation of the thickness of the die. With good process control, the distance “h₂” may be designed down to about 0.01 μm in some embodiments. The smaller the distance “h₂”, the better the heat dissipation with respect to heat generated from the die; therefore, the distance “h₂” may be designed to be smaller than about 10 μm in some embodiments so as to achieve desired heat dissipation capability. In accordance with some embodiments, an overall thickness “h₃” of the heat dissipation component 5 (i.e., a thickness of each of the dummy die portions 511, 512, 513, the interconnection portion 520, and the framing portions 521, 522, 523) may equal a sum of a thickness of the second or third die, the thickness “h₁” of the corresponding covering portion, and the distance “h₂” between the die and the covering portion. In some embodiments where the thickness “h₃” is designed to be its maximum possible value, namely, equaling a thickness of a wafer which is about 800 μm, the thickness “h₁” of the covering portion may be about 780 μm. In comparison to the dummy dies 41. 42, 43 in FIG. 1, the heat dissipation component 5 has a greater total top surface area for heat dissipation, so as to achieve better uniformity and performance in heat dissipation. In accordance with some embodiments, the spaces (e.g., the first space 541 and the second space 542) for accommodating different dies (e.g., the second die 2 and the third die 3) may be made to have the same height even if the dies are different in thickness, so the spaces can be formed together in a single photolithography process, thereby reducing the manufacturing cost.

A glue material 6 is disposed between the heat dissipation component 5 and each of the second die 2 and the third die 3, so as to further secure the dies 2, 3 and the heat dissipation component 5 with respect to the first die 1, and to protect the dies 2, 3 from moisture. In accordance with some embodiments, the glue material 6 may include an organic material, such as epoxy, other suitable materials, or any combination thereof. In accordance with some embodiments, one or more additional substances with good thermal conductivity may be added to the glue material 6 in order to enhance the heat dissipation capability of the glue material 6. The additional substances may include, for example, a two-dimensional (2D) material such as graphene (having a thermal conductivity in a range from about 4400 W/(m·K) to about 5800 W/(m·K)), metal, other suitable materials, or any combination thereof.

In FIG. 13, each of the covering portions 531, 532 is formed with a through hole 551, 552 and an opening 561, 562 in a top surface thereof. Since the covering portions 531, 532 have similar configurations, only the covering portion 532 will be described in more detail for the sake of brevity. Further referring to FIG. 16 that illustrates a sectional view of the heat dissipation component 5 taken along line E1-E1 in FIG. 13, both of the through hole 552 and the opening 562 are in spatial communication with the second space 542. In other words, the opening 562 is in spatial communication with the through hole 552 through the second space 542. In the illustrative embodiment, the through hole 552 serves as a glue inlet for injection of the glue material 6 into the second space 542, and the opening 562 serves as a glue outlet for the glue material 6 to overflow therefrom during the injection. In accordance with some embodiments, the through hole 552 is a circular hole with a diameter greater than about 15 μm to facilitate the injection of the glue material 6. In some embodiments, the through hole 552 may be formed into other shapes and have a sectional area viewed from top not smaller than that of a circular hole with a diameter of about 15 μm. In accordance with some embodiments, the through hole 552 is disposed adjacent to one edge of the third die 3, and the opening 562 is disposed adjacent to the opposite edge of the third die 3. In accordance with some embodiments, the through hole 552 is greater than the opening 562 in size, so as to induce a greater hydraulic pressure during the injection of the glue material 6, facilitating filling up of the second space 542 with the glue material 6.

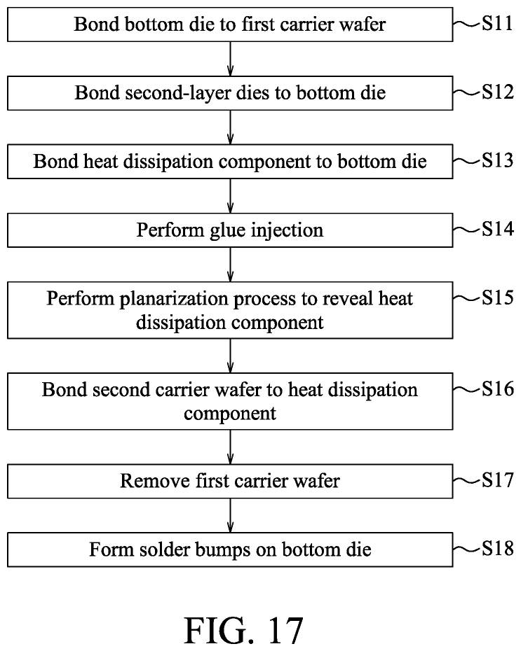

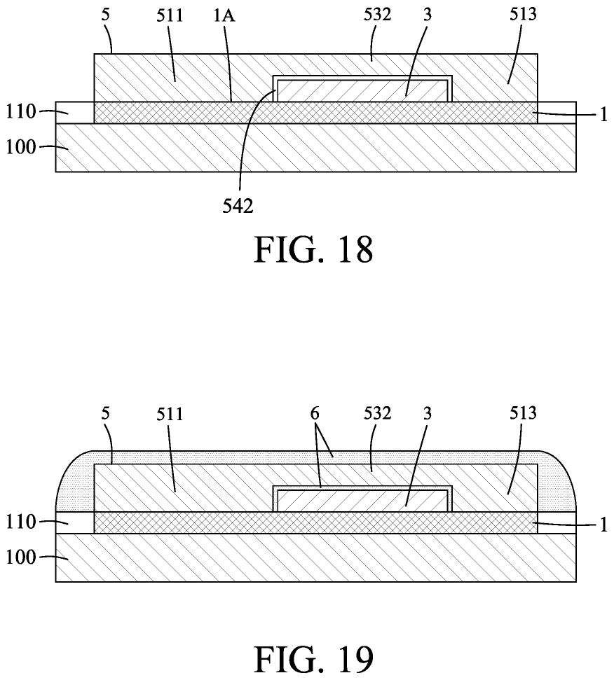

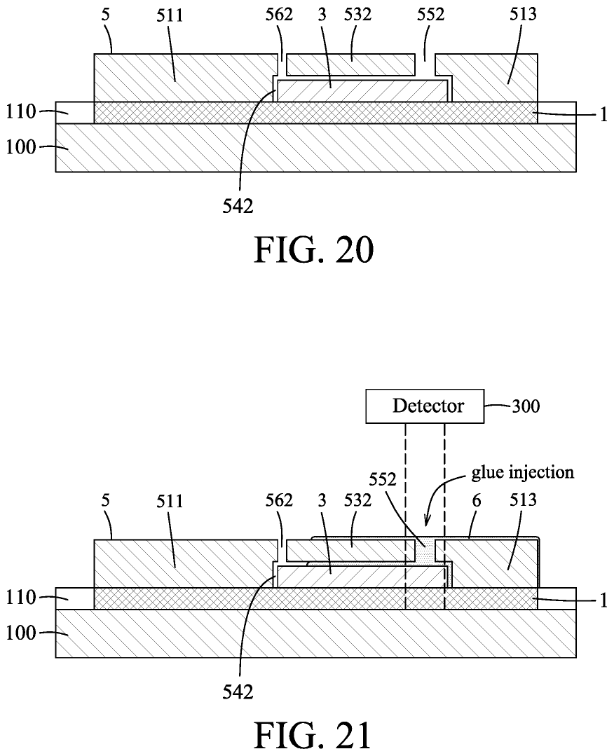

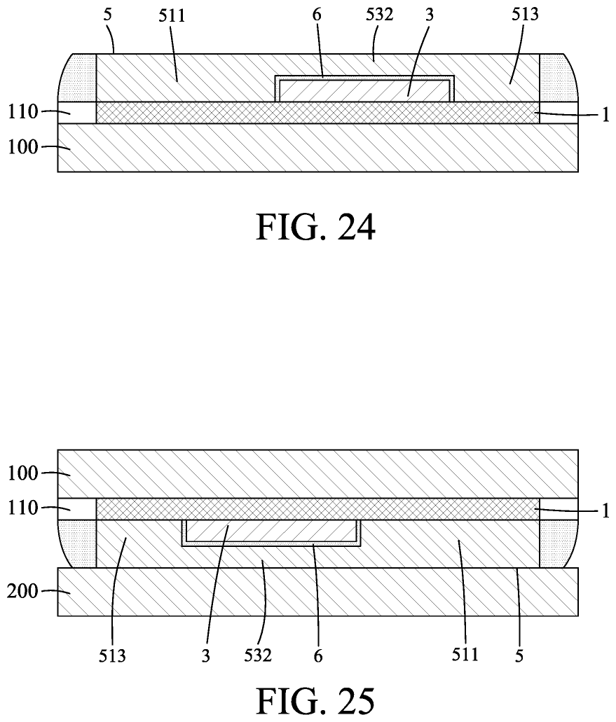

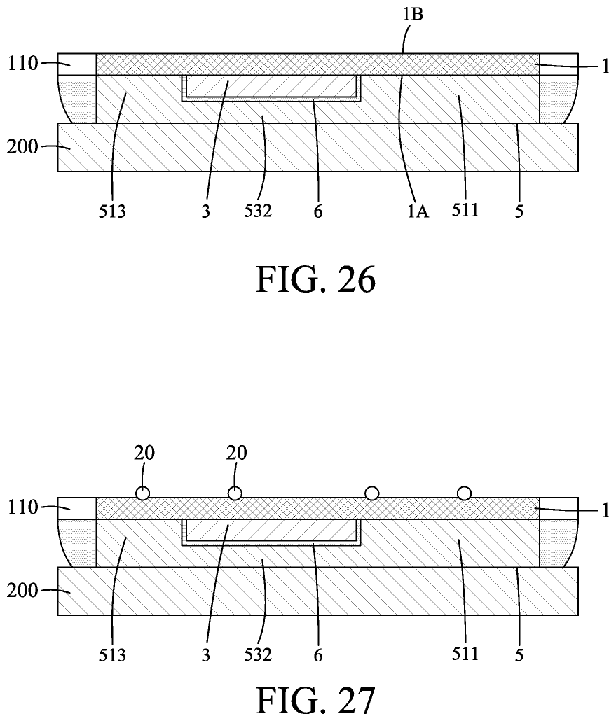

FIG. 17 is a flow chart that cooperates with FIGS. 18 to 27 to illustrate a process for fabricating the stacked semiconductor device as shown in FIG. 13 in accordance with some embodiments, where FIGS. 18, 19 and 24 to 27 are sectional views of structures in intermediate stages of the process that correspond to a sectional view taken along line D-D in FIG. 13, and FIGS. 20 to 23 are sectional views of the structures during a glue injection process that correspond to a section taken along line E1-E1 in FIG. 13. Since steps S11 and S12 are similar to steps S01 and S02 in the flow chart as shown in FIG. 4, details thereof are not repeated herein for the sake of brevity.

Referring to FIGS. 13, 17 and 18, the heat dissipation component 5 is bonded to the first die 1 (step S13) using, for example, fusion bonding, other suitable techniques, or any combination thereof. In accordance with some embodiments, a suction machine (not shown) may be used to pick and place the heat dissipation component 5 onto the first surface 1A of the first die 1 at a position such that the second die 2 and the third die 3 are accommodated in the first space 541 (see FIG. 14) and the second space 542, respectively. Then, an annealing process may be performed to bond the heat dissipation component 5 to the first die 1. In the illustrative embodiment, since the heat dissipation component 5 is made in one piece, the pick-and-place action only needs to be performed once in step S13. Compared to the embodiment as depicted in FIG. 1 where the pick-and-place action has to be performed multiple times respectively with respect to multiple dummy dies, the use of the heat dissipation component 5 may reduce the overall processing time.

In accordance with some embodiments, bonding the heat dissipation component 5 (step S13) may be performed prior to bonding the dies 2, 3 (step S12). In accordance with some embodiments, the dies 2, 3 and the heat dissipation component 5 may all be placed onto the first surface 1A of the first die 1, followed by an annealing process to bond the dies 2, 3 and the heat dissipation component 5 to the first die 1 all together, so as to reduce the overall processing time. However, bonding the dies 2, 3 prior to bonding the heat dissipation component 5 may prevent particle pollutions during the bonding of the dies 2. 3 that might otherwise arise from the picking and placing of the heat dissipation component 5.

Referring to FIGS. 13, 17 and 19, the glue material 6 is injected into the heat dissipation component 5 (step S14) to fill the spaces between the dies 2, 3 and the heat dissipation component 5 (e.g., the first space 541 and the second space 542, see FIGS. 14 and 15). During the injection process, the glue material 6 may flow over the top surface and side surfaces of the heat dissipation component 5. FIGS. 20 to 23 illustrate the process of glue injection in more detail in accordance with some embodiments.

FIG. 20 illustrates a sectional view that corresponds to the section taken along line E1-E1 in FIG. 13 of a structure obtained after step S13, showing that the third die 3 is accommodated in the second space 542, which is in spatial communication with the through hole 552 and the opening 562.

In FIG. 21, the glue material 6 is injected into the second space 542 through the through hole 552. During the injection, the glue material 6 may overflow from the through hole 552, and thus spread over the top surface and the side surface of the heat dissipation component 5.

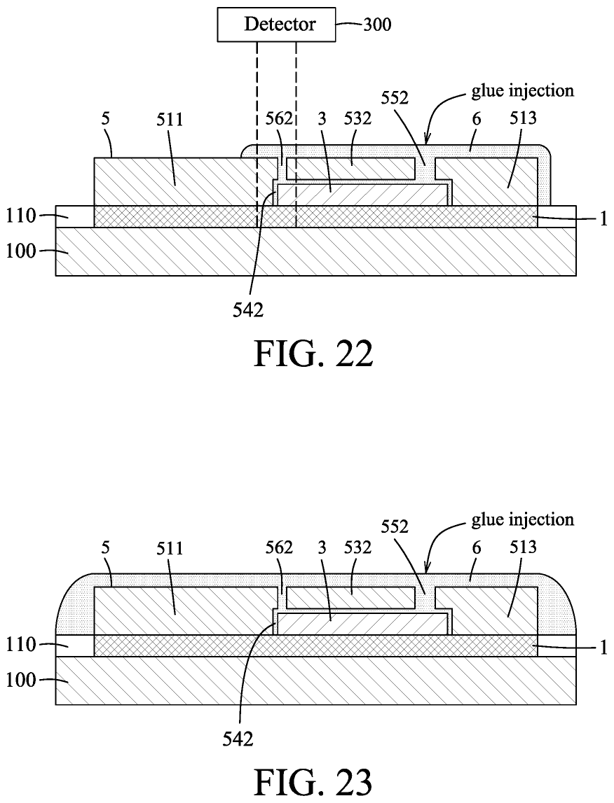

In FIG. 22, the glue material 6 is continuously injected into the second space 542 from the through hole 552, so the glue material 6 overflows from the opening 562 after the second space 542 has been filled up with the glue material 6.

While the glue material 6 is being injected into the second space 542, a detector 300 may be used to detect an internal condition of the heat dissipation component 5 regarding the injection of the glue material 6 in real time. For example, the detector 300 may detect whether there are any voids that are not filled with the glue material 6 present inside the heat dissipation component 5. When a void is detected, the injection parameter (e.g., time or pressure of the injection) may be adjusted immediately to eliminate the void. In accordance with some embodiments, the detector 300 may be realized using, for example, an infrared (IR) detector, detectors of other suitable types, or any combination thereof.

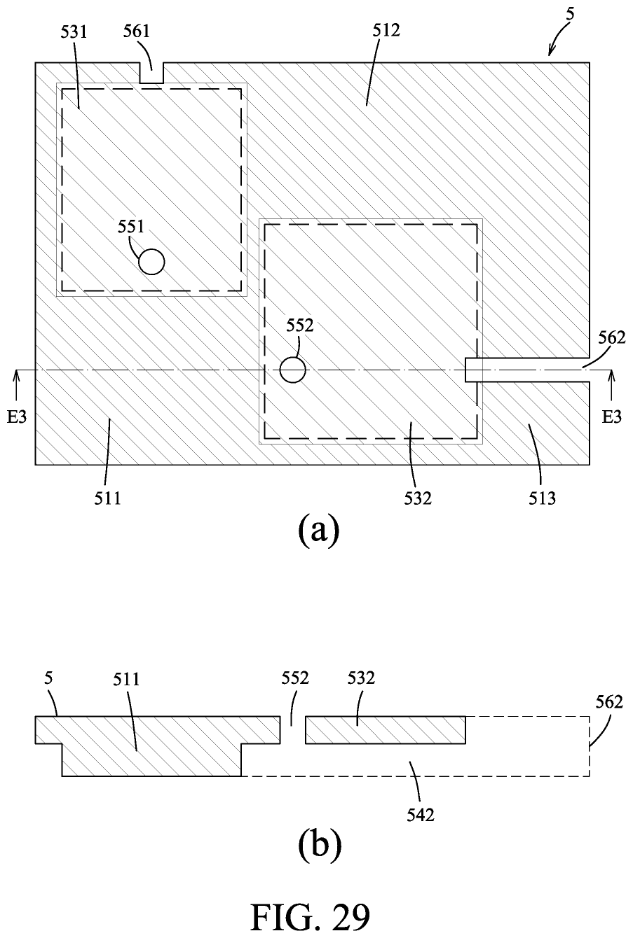

In FIG. 23, the injection of the glue material 6 is completed, with the glue material 6 being disposed over the top surface and the side surfaces of the heat dissipation component 5. In accordance with some embodiments, it is not necessary to make the glue material 6 fully cover the heat dissipation component 5 (i.e., covering the entire top and side surfaces of the heat dissipation component 5). Then, an annealing process may be performed to solidify the glue material 6. In the illustrative embodiment, since the glue material 6 fills up the through hole 552 and the opening 562 that both extend in a vertical direction perpendicular to a surface of the first die 1 to which the heat dissipation component 5 is bonded, the solidified glue material 6 has a first extending portion that extends through the covering portion 532 from the through hole 552, and a second extending portion that extends through the covering portion 532 from the opening 562, where each of the first extending portion and the second extending portion extends in the vertical direction. In some embodiments where the heat dissipation component 5 is formed with one or more glue outlets in one or more side surfaces thereof (e.g., openings 561. 562 as illustrated in FIGS. 29, 30 and 32), the solidified glue material 6 may form one or more extending portions (respectively corresponding to the glue outlets) that extend through one or more sidewalls of the heat dissipation component 5 in direction(s) parallel to the surface of the first die 1 to which the heat dissipation component 5 is bonded.

Referring to FIGS. 13, 17 and 24, a planarization process is performed on the solidified glue material 6 (step S15) to reveal the top surface of the heat dissipation component 5. In accordance with some embodiments, the planarization process may be, for example, a CMP process, other suitable processes, or any combination thereof. Because the heat dissipation component 5 usually has a thermal conductivity greater than that of the glue material 6, revealing the top surface of the heat dissipation component 5 may favor heat dissipation.

Referring to FIGS. 13, 17 and 25, a second carrier wafer 200 is bonded to the heat dissipation component 5, and then the combined wafers and dies are flipped over for the following processes (step S16). In some embodiments, a bonding dielectric film (not shown) may be formed over the heat dissipation component 5, and then the second carrier wafer 200 may be bonded to the bonding dielectric film using, for example, fusion bonding, other suitable techniques, or any combination thereof. The second carrier wafer 200 is used for enhancing overall mechanical strength of the structure, so as to prevent mechanical damage from subsequent process steps. In accordance with some embodiments where the heat dissipation component 5 is thick enough (e.g., greater than 600 μm) to provide sufficient mechanical strength for the following process steps, the bonding of the second carrier wafer 200 can be omitted.

Referring to FIGS. 13, 17 and 26, the first carrier wafer 100 (see FIG. 25) is removed (step S17) using, for example, a CMP process, a grinding process, other suitable thinning techniques, or any combination thereof so as to reveal the second surface 1B of the first die 1.

Referring to FIGS. 13, 17 and 27, a plurality of solder bumps 20 are formed onto the first die 1 (step S18) to connect with the conductive pads 18 of the first die 1 (see FIG. 3).

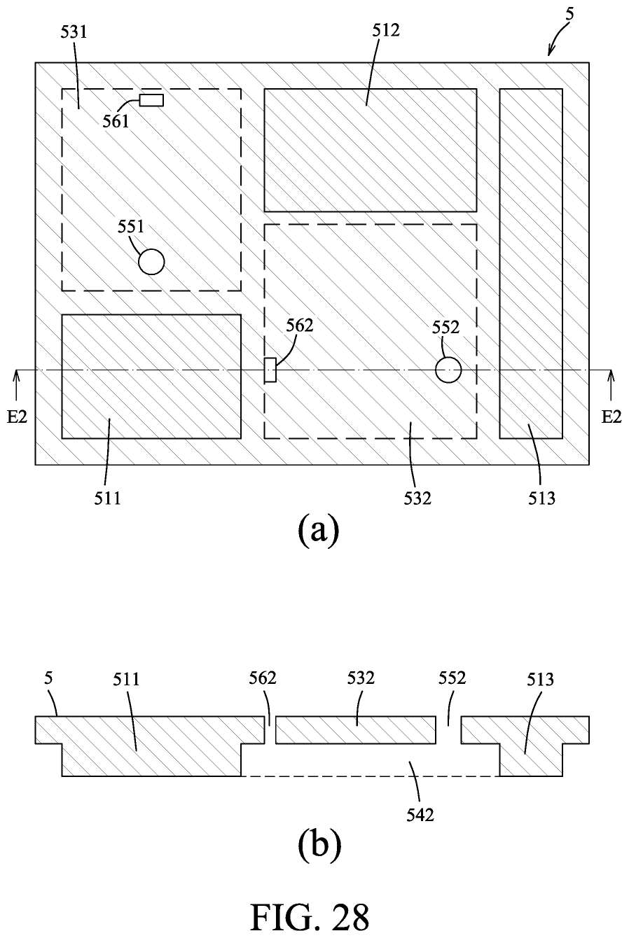

FIGS. 28 to 35 illustrate several variations of the heat dissipation component 5 in accordance with some embodiments, where areas represented by dotted blocks correspond in position to where the aforesaid second die 2 and third die 3 would be positioned.

In FIG. 28, a first variation of the heat dissipation component 5 is provided in accordance with some embodiments. In the illustrative variation, the heat dissipation component 5 includes a first dummy die portion 511, a second dummy die portion 512 and a third dummy die portion 513 that are to be bonded to a die in a lower layer (e.g., the aforesaid first die 1), where part (a) of FIG. 28 illustrates a top view of the heat dissipation component 5, and part (b) of FIG. 28 illustrates a sectional view of the heat dissipation component 5 taken along line E2-E2 in part (a). The first dummy die portion 511 and the second dummy die portion 512 are to be adjacent to two of the edges of the aforesaid second die 2, respectively. The first dummy die portion 511, the second dummy die portion 512 and third dummy die portion 513 are to be adjacent to three of the edges of the aforesaid third die 3, respectively. The other portions of the heat dissipation component 5, including covering portions 531, 532, are hanging portions that are thinner than the dummy die portions 511, 512, 513 and that would not be bonded to the aforesaid first die 1. The hanging portions interconnect the dummy die portions 511, 512, 513, with the top surfaces of the hanging portions being coplanar with the top surfaces of the dummy die portions 511, 512, 513. Such a configuration may provide a larger space for accommodating the aforesaid dies 2, 3 in comparison to the configuration shown in FIG. 13, allowing a greater tolerance for placing the heat dissipation component 5 onto the aforesaid first die 1.

FIG. 29 illustrates a second variation of the heat dissipation component 5 that is similar to the heat dissipation component 5 in FIG. 13 in accordance with some embodiments. In the illustrative variation, part (a) of FIG. 29 illustrates a top view of the heat dissipation component 5, and part (b) of FIG. 29 illustrates a sectional view of the heat dissipation component 5 taken along line E3-E3 in part (a). In this variation, each of the openings 561, 562 of the heat dissipation component 5 is formed in a side surface of the heat dissipation component 5 for allowing the excess glue material 6 to flow out of the heat dissipation component 5 in a lateral direction during the glue injection process, and is formed as an uncovered channel that penetrates the top surface and the bottom surface of the heat dissipation component 5 and that extends to and spatially communicates with a respective one of the first space 541 under the covering portion 531 and the second space 542 under the covering portion 532.

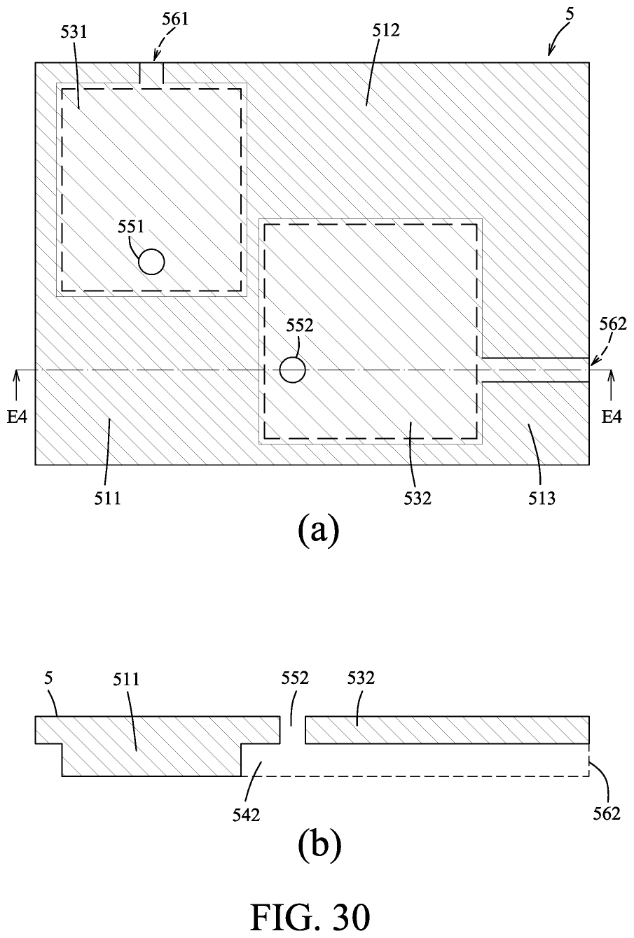

FIG. 30 illustrates a third variation of the heat dissipation component 5 that is similar to second variation of the heat dissipation component 5 in FIG. 29 in accordance with some embodiments. In the illustrative variation, part (a) of FIG. 30 illustrates a top view of the heat dissipation component 5, and part (b) of FIG. 30 illustrates a sectional view of the heat dissipation component 5 taken along line E4-E4 in part (a). In this variation, each of the openings 561, 562 of the heat dissipation component 5 is formed in a side surface of the heat dissipation component 5 for allowing the excess glue material 6 to flow out of the heat dissipation component 5 in a lateral direction, and is formed as a tunnel that is covered by the top surface of the heat dissipation component 5 and that extends to and spatially communicates with a respective one of the first space 541 under the covering portion 531 and the second space 542 under the covering portion 532. In the illustrative embodiment, the covering portions 531, 532 extend to cover the openings 561. 562, respectively.

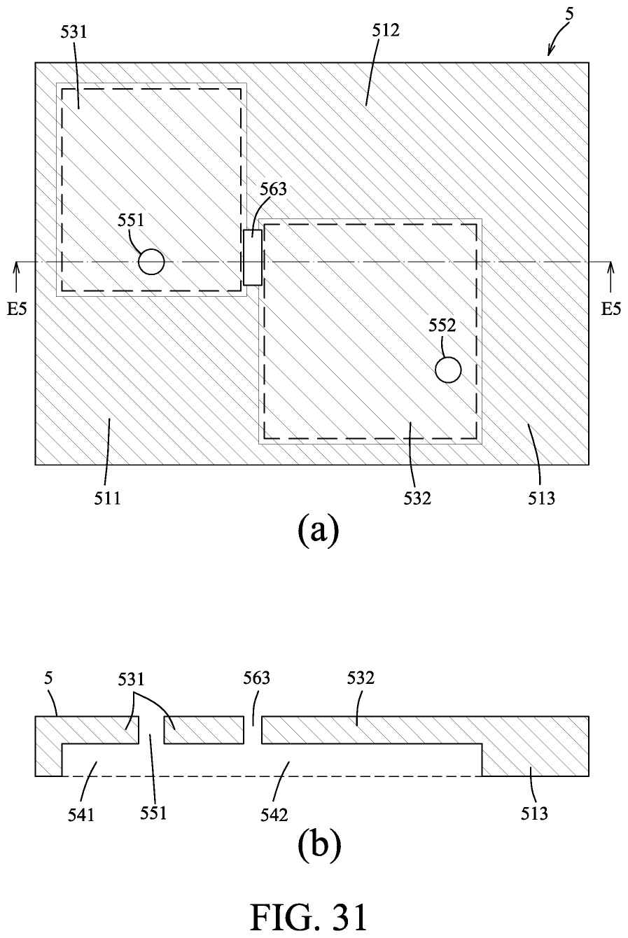

FIG. 31 illustrates a fourth variation of the heat dissipation component 5 that is similar to the heat dissipation component 5 in FIG. 13 in accordance with some embodiments. In the illustrative variation, part (a) of FIG. 31 illustrates a top view of the heat dissipation component 5, and part (b) of FIG. 31 illustrates a sectional view of the heat dissipation component 5 taken along line E5-E5 in part (a). In this variation, the top surface of the heat dissipation component 5 is formed with an opening 563 that extends from the first covering portion 531 to the second covering portion 532, so that the opening 563 spatially interconnects the first space 541 under the first covering portion 531 and the second space 542 under the second covering portion 532. As a result, the first space 541 is spatially connected to the second space 542 via the opening 563, and the glue material 6 can flow between the first space 541 and the second space 542 during the glue injection process. Since the heat dissipation component 5 may need at least one glue inlet and at least one glue outlet for the glue injection process, in such a configuration, the opening 563 can be used as either a glue inlet or a glue outlet, and at least one of the through holes 551, 552 can be used as a glue outlet (when the opening 563 is used as a glue inlet) or a glue inlet (when the opening 563 is used as a glue outlet). In accordance with some embodiments, one of the through holes 551, 552 can be omitted. In accordance with some embodiments, the heat dissipation component 5 may be formed with additional opening(s) in the top surface and/or side surfaces of the heat dissipation component 5 as illustrated in FIGS. 13, 28, 29, 30 for injection and/or outflow of the glue material 6.

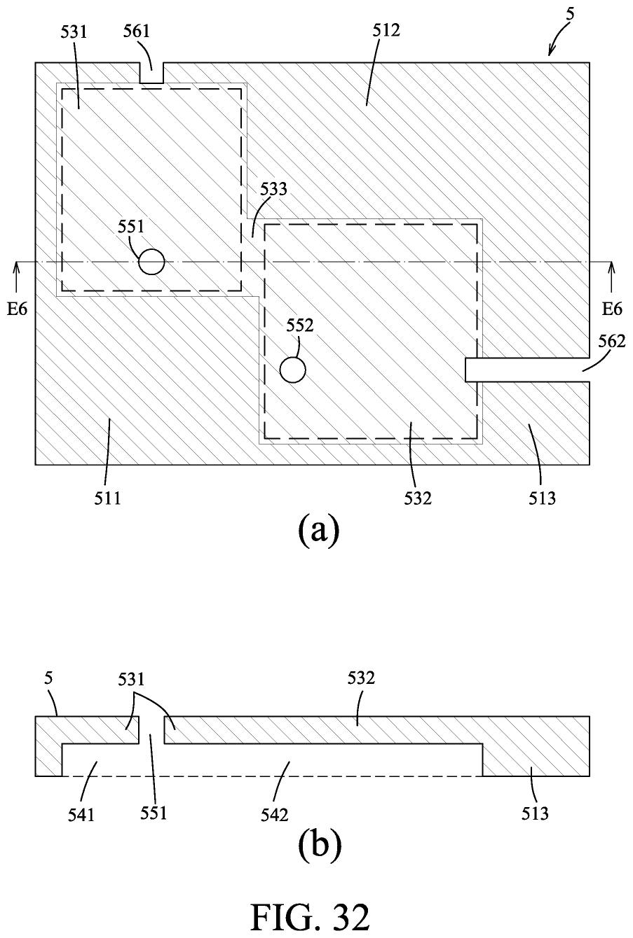

FIG. 32 illustrates a fifth variation of the heat dissipation component 5 that is similar to the fourth variation of the heat dissipation component 5 in FIG. 31 in accordance with some embodiments. In the illustrative variation, part (a) of FIG. 32 illustrates a top view of the heat dissipation component 5, and part (b) of FIG. 32 illustrates a sectional view of the heat dissipation component 5 taken along line E6-E6 in part (a). In this variation, an interconnection portion 533 of the heat dissipation component 5 between the covering portions 531, 532 is a hanging portion that would not be bonded to the aforesaid first die 1 and that interconnects the covering portions 531. 532 (namely, the covering portions 531, 532 and the interconnection portion 533 are integrated as a large hanging piece), so the first space 541 under the first covering portion 531 is spatially connected with the second space 542 under the second covering portion 532 through a space under the interconnection portion 533. In the illustrative embodiment, the heat dissipation component 5 is formed with the openings 561, 562 as illustrated in FIG. 32, but this variation is not limited in this respect. In some embodiments, the through holes 551, 552 can be used as a glue inlet-outlet pair, and the openings 561, 562 can be omitted. In some embodiments, the heat dissipation component 5 can be formed with only one of the through holes 551, 552 that serves as a glue inlet, and only one of the openings 561, 562 that serves as a glue outlet.

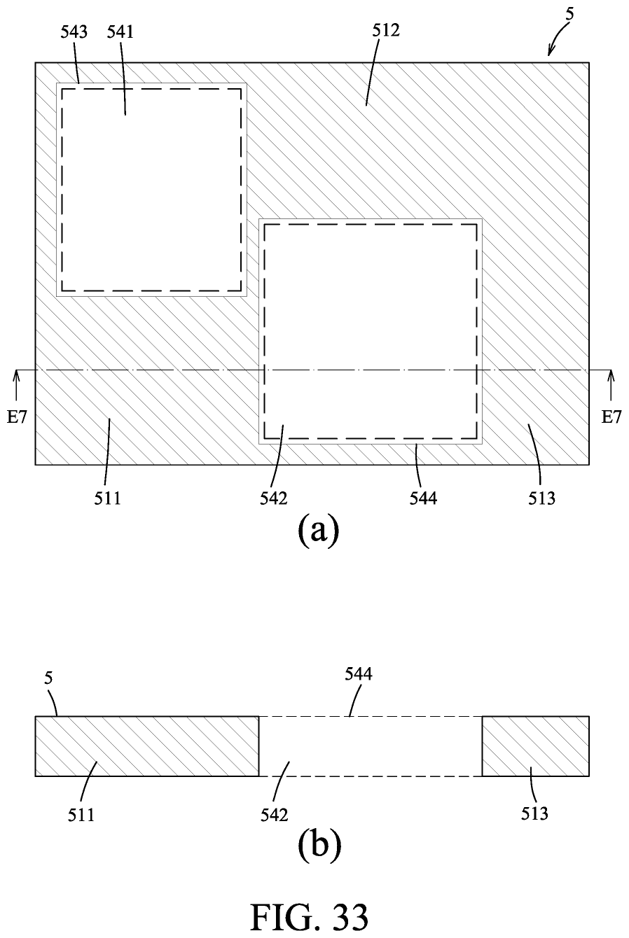

FIG. 33 illustrates a sixth variation of the heat dissipation component 5 that is similar to the heat dissipation component 5 in FIG. 13 in accordance with some embodiments. In the illustrative variation, part (a) of FIG. 33 illustrates a top view of the heat dissipation component 5, and part (b) of FIG. 33 illustrates a sectional view of the heat dissipation component 5 taken along line E7-E7 in part (a). In this variation, the covering portions 531, 532 in FIG. 13 are omitted, so the top surface of the heat dissipation component 5 is formed with a first opening 543 that is spatially connected with the first space 541, and a second opening 544 that is spatially connected with the first space 542. In accordance with some embodiments, the first opening 543 is aligned with and has the same length and width as the first space 541, and a second opening 544 is aligned with and has the same length and width as the second space 542. With the openings 543, 544, the glue material 6 can be directly dispensed onto the dies 2 and 3 through the openings 543, 544 at a greater flow rate, so as to reduce time required by the glue injection process.

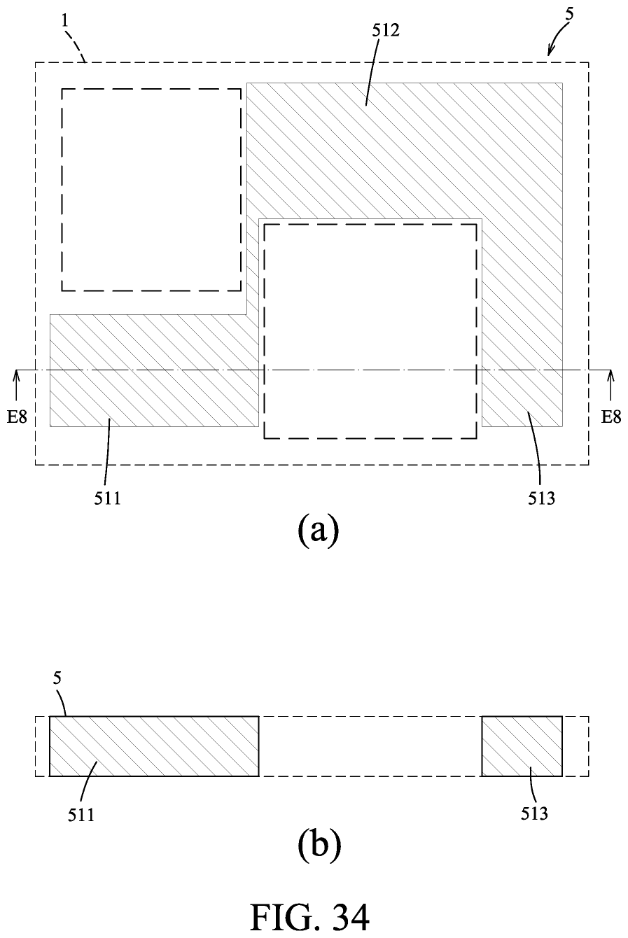

FIG. 34 illustrates a seventh variation of the heat dissipation component 5 that is similar to the sixth variation of the heat dissipation component 5 in FIG. 33 in accordance with some embodiments. In the illustrative variation, part (a) of FIG. 34 illustrates a top view of the heat dissipation component 5, and part (b) of FIG. 34 illustrates a sectional view of the heat dissipation component 5 taken along line E8-E8 in part (a). In this variation, the heat dissipation component 5 is made smaller than the first die 1 in length and width, and is configured to not enclose or fully surround the dies 2, 3. When the heat dissipation component 5 is placed on the aforesaid first die 1 at a predetermined position to be adjacent to the aforesaid dies 2, 3, the edges of the heat dissipation component 5 would be disposed within a boundary that is defined by the edges of the first die 1, and would be spaced apart from the edges of the first die 1 in lateral directions.

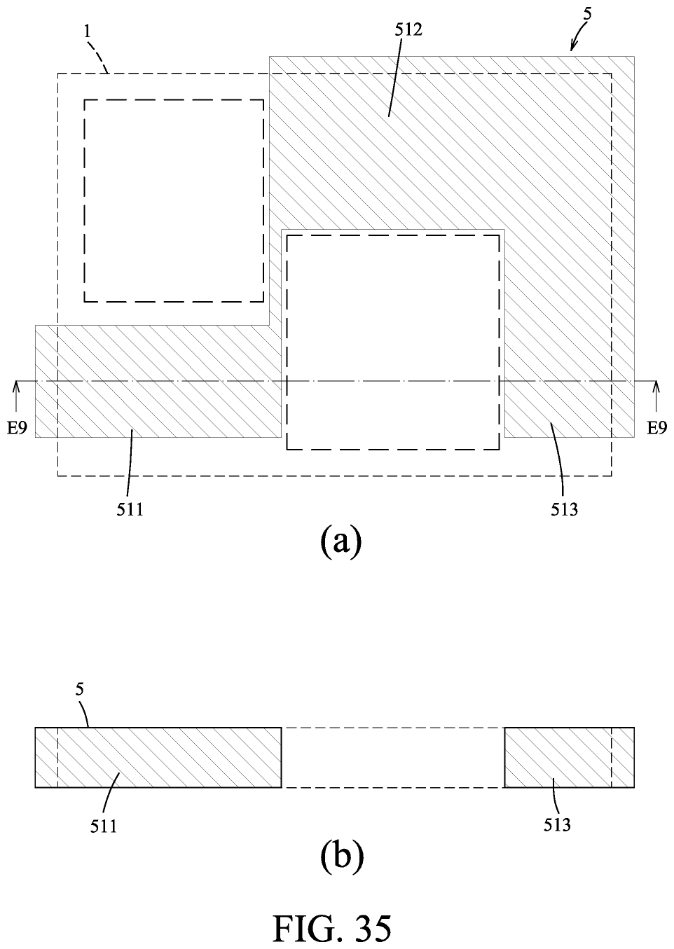

FIG. 35 illustrates an eighth variation of the heat dissipation component 5 that is similar to the seventh variation of the heat dissipation component 5 in FIG. 34 in accordance with some embodiments. In the illustrative variation, part (a) of FIG. 35 illustrates a top view of the heat dissipation component 5, and part (b) of FIG. 35 illustrates a sectional view of the heat dissipation component 5 taken along line E9-E9 in part (a). In this variation, the heat dissipation component 5 is made to extend beyond a boundary that is defined by the edges of the first die 1 in some lateral directions, so some of the edges of the heat dissipation component 5 are disposed outside of the first die 1 and spaced apart from the adjacent edges of the first die 1 when the heat dissipation component 5 is placed on the first die 1 at a predetermined position to be adjacent to the aforesaid dies 2, 3.

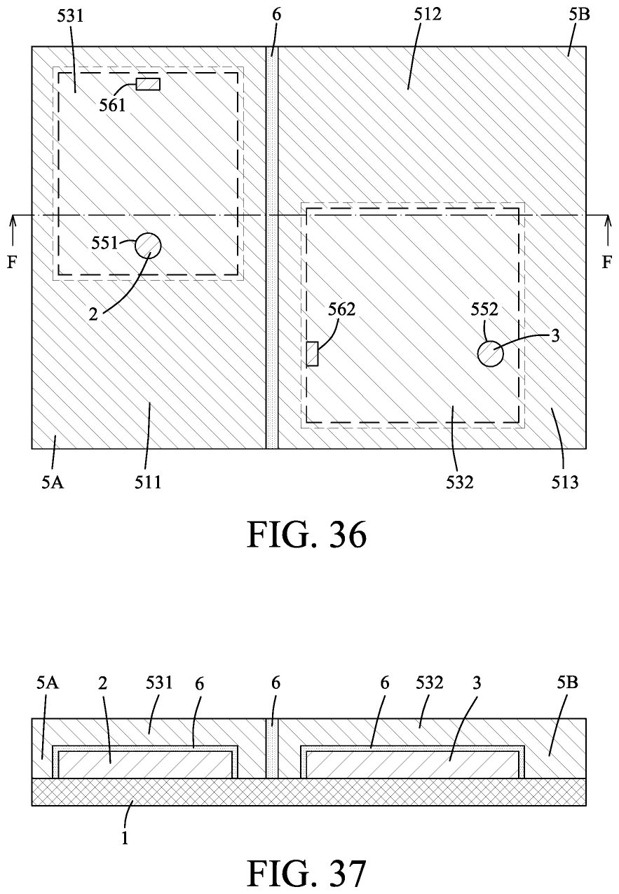

Referring to FIGS. 36 and 37, the heat dissipation structure of the stacked semiconductor device includes multiple heat dissipation components 5A, 5B respectively for the dies 2. 3 in accordance with some embodiments, where FIG. 36 illustrates a top view of the stacked semiconductor device, and FIG. 37 illustrates a sectional view of the stacked semiconductor device taken along line F-F in FIG. 36. In the illustrative embodiment, the heat dissipation components 5A, 5B are bonded to the first die 1, and are spaced apart from each other. Each of the heat dissipation components 5A, 5B is formed with a space to accommodate the respective one of the dies 2, 3. To be specific. the heat dissipation component 5A includes a first bonding portion and a first covering portion 531. The first bonding portion is bonded to the first die 1, surrounds the second die 2, and includes a dummy die portion 511. The first covering portion 531 is connected to the bonding portion, and is disposed over and covers the second die 2. The heat dissipation component 5B includes a second bonding portion and a second covering portion 532. The bonding portion is bonded to the first die 1, surrounds the third die 3, and includes dummy die portions 512, 513. The second covering portion 532 is connected to the second bonding portion, and is disposed over and covers the third die 3. In accordance with some embodiments, the top surfaces of the heat dissipation components 5A, 5B are coplanar. After the glue injection process, the glue material 6 fills up the spaces that accommodate the dies 2, 3, and is filled in a gap between the heat dissipation components 5A, 5B.

In accordance with some embodiments, the aforesaid heat dissipation components 5, 5A, 5B may be adapted for use with dies in a top layer of the stacked semiconductor device, and the number of layers of the stacked semiconductor device may vary. For example, when the stacked semiconductor device includes three layers of dies that are stacked together, such as a first die layer, a second die layer and a third die layer from bottom to top, the aforesaid heat dissipation components 5, 5A, 5B may be used in the third die layer.

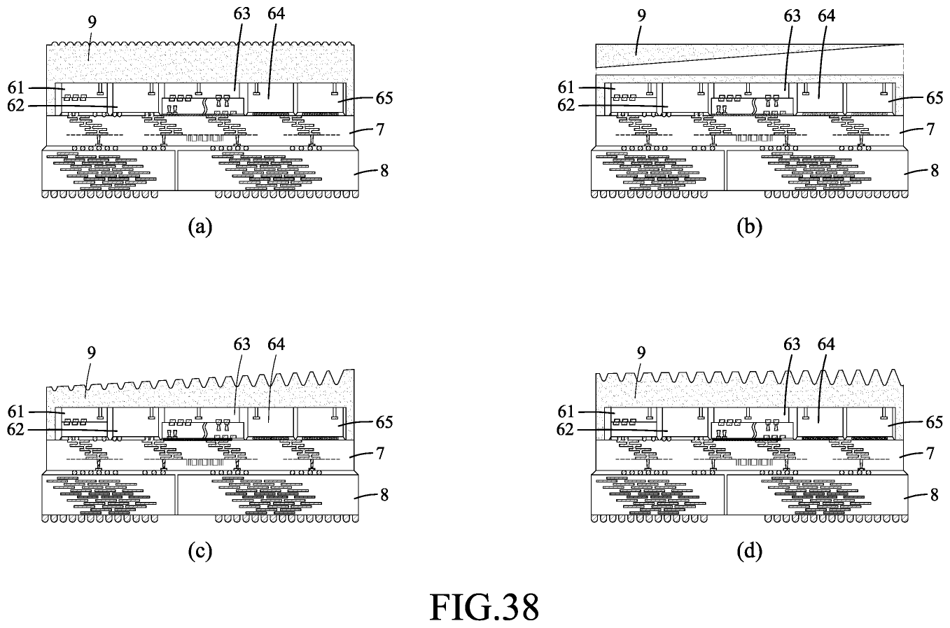

FIG. 38 illustrates various examples of final products that include the stacked semiconductor device in accordance with some embodiments. In the examples shown in parts (a) to (d) of FIG. 38, multiple chips 61 to 65 are bonded to an interposer 7, and are electrically connected to a substrate 8 through the interposer 7, so electric signals may be transmitted among the chips 61 to 65 through the interposer 7 and the substrate 8. Some of the chips 61 to 65 may be made to have a structure of the stacked semiconductor device according to some embodiments of this disclosure (namely, using the aforesaid heat dissipation components 5, 5A, 5B). Although the chips 61 to 65 may have their own heat dissipation structures, the final products may each be formed with an additional cooling structure 9 over the chips 61 to 65. The cooling structure 9 may be made of, for example, a heat dissipation glue that can come in different forms (e.g., having jagged surfaces of different types, formed to have some voids, etc.) as illustrated in parts (a) to (d) of FIG. 38, other suitable structures, or any combination thereof.

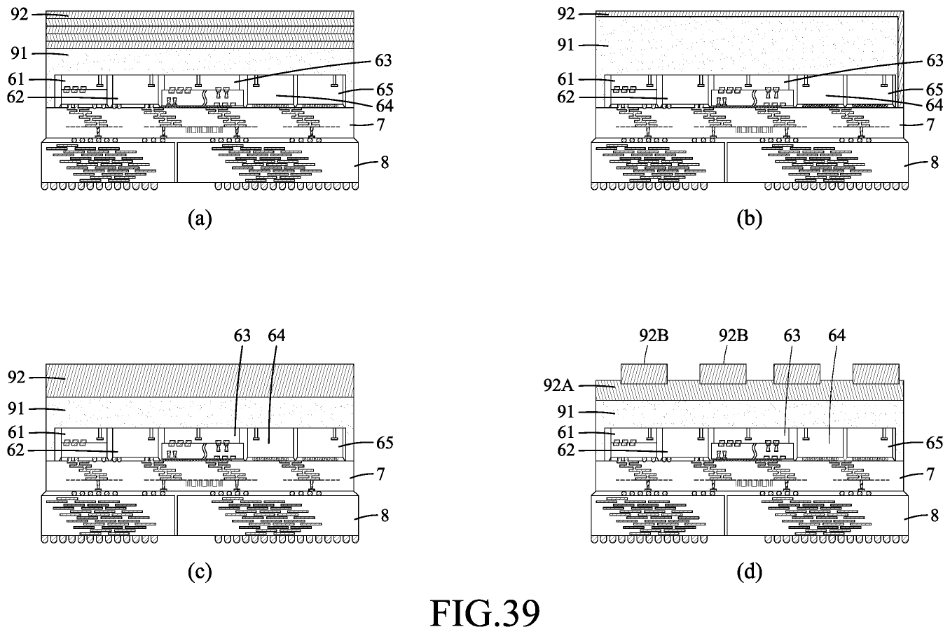

FIG. 39 also illustrates some other examples of final products that include the stacked semiconductor device in accordance with some embodiments. In FIG. 39, the cooling structure may include a heat dissipation glue 91 and a heat sink 92 that is made of metal, where the heat dissipation glue 91 serves as an adhesive between the heat sink 92 and the chips 61 to 65. The heat sink 92 may have different structures. In part (a) of FIG. 39, the heat sink 92 may be a metal seat that includes multiple layers of different metals; in part (b) of FIG. 39, the heat sink 92 may include a first metal sheet portion that contacts a top surface of the heat dissipation glue 91, and a second metal sheet portion that contacts a side surface of the heat dissipation glue 91; in part (c) of FIG. 39, the heat sink 92 may be a metal base of a single metal material that is disposed over the heat dissipation glue 91; and in part (d) of FIG. 39, the heat sink may include a metal layer 92A that covers the heat dissipation glue 91, and multiple metal components 92B that are arranged on and disposed over the metal layer 92A, where the metal layer 92A and the metal components 92B are made of different metal materials.

To sum up, in some embodiments of this disclosure, the heat dissipation component is formed in one piece to correspond in position to unoccupied space on the die(s) in the lower layer, so a number of the pick-and-place action to put the heat dissipation component onto the die(s) in the lower layer can be reduced, shortening the overall processing time. In some embodiments of this disclosure, the heat dissipation component is formed as a cap that includes one or more covering portions that are disposed over and cover the dies, so as to acquire a larger heat dissipation area, and achieve uniform and better heat dissipation. When the heat dissipation component is thick enough, the second carrier wafer may be omitted during the removal of the first carrier wafer and the formation of solder bumps, so the process can be simplified and the material cost can be reduced.

In accordance with some embodiments, a stacked semiconductor device is provided to include a first die, a second die that is bonded to the first die, a third die that is bonded to the first die, and a heat dissipation component that is formed in one piece and that is bonded to the first die. The heat dissipation component is adjacent to at least two edges of each of the second die and the third die.

In accordance with some embodiments, the heat dissipation component includes a semiconductor material.

In accordance with some embodiments, the heat dissipation component includes a covering portion that covers at least one of the second die or the third die.

In accordance with some embodiments, the heat dissipation component surrounds the second die and the third die, and is formed with a first space that accommodates the second die, and a second space that accommodates the third die. The first space and the second space spatially communicate with each other.

In accordance with some embodiments, the heat dissipation component laterally surrounds each of the second die and the third die.

In accordance with some embodiments, the stacked semiconductor device further includes a material disposed between the heat dissipation component and each of the second die and the third die.

In accordance with some embodiments, the heat dissipation component includes a covering portion that covers at least one of the second die or the third die, and the material disposed between the heat dissipation component and each of the second die and the third die has a first extending portion that extends through the covering portion.

In accordance with some embodiments, the material disposed between the heat dissipation component and each of the second die and the third die has a second extending portion that is spaced apart from the first extending portion, and that extends through one of the covering portion and a sidewall of the heat dissipation component.

In accordance with some embodiments, the material disposed between the heat dissipation component and each of the second die and the third die includes a two-dimensional material.

In accordance with some embodiments, a stacked semiconductor device is provided to include a first die, a second die bonded to the first die, and a heat dissipation cap component bonded to the first die, and covering the second die. The heat dissipation cap component has a thermal conductivity greater than that of SiO₂.

In accordance with some embodiments, the heat dissipation cap component includes single-crystal silicon.

In accordance with some embodiments, the stacked semiconductor device further includes a glue material disposed between the second die and the heat dissipation cap component.

In accordance with some embodiments, the heat dissipation cap component includes a covering portion disposed over the second die, and the covering portion is formed with a through hole over the second die.

In accordance with some embodiments, the heat dissipation cap component is formed with an opening in one of the covering portion and a side surface of the heat dissipation cap component, and the opening is in spatial communication with the through hole through a space where the second die is disposed.

In accordance with some embodiments, the stacked semiconductor device further includes a third die bonded to the first die, and another heat dissipation cap component bonded to the first die and covering the third die. The heat dissipation cap component and the another heat dissipation cap component are spaced apart from each other.

In accordance with some embodiments, the stacked semiconductor device further includes a third die bonded to the first die. The heat dissipation cap component is formed in one piece and further covers the third die.

In accordance with some embodiments, a method is provided for fabricating a stacked semiconductor device. In one step, a first die is provided, and a second die and a third die are bonded to the first die. In one step, a heat dissipation component is placed onto the first die at a position so that the heat dissipation component is adjacent to at least two edges of each of the second die and the third die. The heat dissipation component is formed in one piece. In one step, the heat dissipation component is bonded to the first die.

In accordance with some embodiments, the heat dissipation component is formed with a space, and has a covering portion corresponding in position to the space. In the step of placing the heat dissipation component onto the first die, the heat dissipation component is placed at the position so that one of the second die and the third die is accommodated in the space of the heat dissipation component, and that the covering portion covers the one of the second die and the third die.

In accordance with some embodiments, the covering portion is formed with a glue inlet hole in spatial communication with the space that accommodates the one of the second die and the third die. In one step of the method, a glue material is injected into the space through the glue inlet hole.

In accordance with some embodiments, the heat dissipation component is formed with a glue outlet opening in one of the covering portion and a side surface of the heat dissipation component, and the glue outlet opening is in spatial communication with the space that accommodates the one of the second die and the third die. In one step of the method, the injection of the glue material is terminated after the glue material overflows from the glue outlet opening.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A stacked semiconductor device, comprising:
a first die;
a second die that is bonded to the first die;
a third die that is bonded to the first die; and
a heat dissipation component that is formed in one piece and that is bonded to the first die;
wherein the heat dissipation component is adjacent to at least two edges of each of the second die and the third die.

2. The stacked semiconductor device according to claim 1, wherein the heat dissipation component includes a semiconductor material.

3. The stacked semiconductor device according to claim 1, wherein the heat dissipation component includes a covering portion that covers at least one of the second die or the third die.

4. The stacked semiconductor device according to claim 1, wherein the heat dissipation component surrounds the second die and the third die, and is formed with a first space that accommodates the second die, and a second space that accommodates the third die; and
wherein the first space and the second space spatially communicate with each other.

5. The stacked semiconductor device according to claim 1, wherein the heat dissipation component laterally surrounds each of the second die and the third die.

6. The stacked semiconductor device according to claim 1, further comprising a material disposed between the heat dissipation component and each of the second die and the third die.

7. The stacked semiconductor device according to claim 6, wherein the heat dissipation component includes a covering portion that covers at least one of the second die or the third die, and the material disposed between the heat dissipation component and each of the second die and the third die has a first extending portion that extends through the covering portion.

8. The stacked semiconductor device according to claim 7, wherein the material disposed between the heat dissipation component and each of the second die and the third die has a second extending portion that is spaced apart from the first extending portion, and that extends through one of the covering portion and a sidewall of the heat dissipation component.

9. The stacked semiconductor device according to claim 6, wherein the material disposed between the heat dissipation component and each of the second die and the third die includes a two-dimensional material.

10. A stacked semiconductor device, comprising:
a first die;
a second die bonded to the first die; and
a heat dissipation cap component bonded to the first die, and covering the second die;
wherein the heat dissipation cap component has a thermal conductivity greater than that of SiO₂.

11. The stacked semiconductor device according to claim 10, wherein the heat dissipation cap component includes single-crystal silicon.

12. The stacked semiconductor device according to claim 10, further comprising a glue material disposed between the second die and the heat dissipation cap component.

13. The stacked semiconductor device according to claim 10, wherein the heat dissipation cap component includes a covering portion disposed over the second die, and the covering portion is formed with a through hole over the second die.

14. The stacked semiconductor device according to claim 13, wherein the heat dissipation cap component is formed with an opening in one of the covering portion and a side surface of the heat dissipation cap component, and the opening is in spatial communication with the through hole through a space where the second die is disposed.

15. The stacked semiconductor device according to claim 10, further comprising a third die bonded to the first die, and another heat dissipation cap component bonded to the first die and covering the third die;
wherein the heat dissipation cap component and the another heat dissipation cap component are spaced apart from each other.

16. The stacked semiconductor device according to claim 10, further comprising a third die bonded to the first die, wherein the heat dissipation cap component is formed in one piece and further covers the third die.

17. A method for fabricating a stacked semiconductor device, comprising:
bonding, to a first die, a second die and a third die;
placing a heat dissipation component that is formed in one piece onto the first die at a position so that the heat dissipation component is adjacent to at least two edges of each of the second die and the third die; and
bonding the heat dissipation component to the first die.

18. The method according to claim 17, wherein the heat dissipation component is formed with a space, and has a covering portion corresponding in position to the space; and
wherein, in the step of placing the heat dissipation component onto the first die, the heat dissipation component is placed at the position so that one of the second die and the third die is accommodated in the space of the heat dissipation component, and that the covering portion covers the one of the second die and the third die.

19. The method according to claim 18, wherein the covering portion is formed with a glue inlet hole in spatial communication with the space that accommodates the one of the second die and the third die;
the method further comprising a step of injecting a glue material into the space through the glue inlet hole.

20. The method according to claim 19, wherein the heat dissipation component is formed with a glue outlet opening in one of the covering portion and a side surface of the heat dissipation component, and the glue outlet opening is in spatial communication with the space that accommodates the one of the second die and the third die;
the method further comprising a step of terminating the injection of the glue material after the glue material overflows from the glue outlet opening.
